(19) United States
(12) Patent Application Publication
(10) Pub. No.: US 2017/0068055 A1
(43) Pub. Date: Mar. 9, 2017

(54) OPTICAL MODULE CONNECTOR AND PRINTED BOARD ASSEMBLY

(71) Applicant: FUJITSU LIMITED, Kawasaki-shi (JP)

(72) Inventors: Yasushi Masuda, Kawasaki (JP); YOSHIHIRO MORITA, Yokohama (JP); Satoshi Ohsawa, Kawasaki (JP); Yohei Miura, Kawasaki (JP)

(73) Assignee: FUJITSU LIMITED, Kawasaki-shi (JP)

(21) Appl. No.: 15/247,191

(22) Filed: Aug. 25, 2016

(30) Foreign Application Priority Data
Sep. 4, 2015 (JP) 2015-175134

(51) Int. Cl. G02B 6/38; G02B 6/42; H05K 1/18

(52) U.S. Cl. CPC G02B 6/3897; H05K 1/18; G02B 6/4238; G02B 6/4292; G02B 6/4244; G02B 6/428; H05K 2201/10121; H05K 2201/10568; H05K 2201/10962

(57) ABSTRACT

An optical module connector includes a connector configured to be coupled to a package substrate, which is coupled to first solder coupled to a printed board, and to second solder coupled to the printed board, the connector being coupled to the second solder; and an optical-module substrate configured to be detachably coupled to the connector, wherein the connector configured to include a first surface to which the optical-module substrate is coupled, a second surface coupled to the package substrate, and a third surface coupled to the second solder, and wherein the first surface to which the optical-module substrate is coupled includes a fourth surface opposite the second surface and a fifth surface opposite the third surface coupled to the second solder, and wherein a first height from the second surface to the first surface is less than a second height from the third surface to the first surface.

### CROSS-REFERENCE TO RELATED APPLICATION

This application is based upon and claims the benefit of priority of the prior Japanese Patent Application No. 2015-175134, filed on Sep. 4, 2015, the entire contents of which are incorporated herein by reference.

### FIELD

The embodiments discussed herein are related to optical module connectors and printed board assemblies.

### BACKGROUND

With speed enhancement of high-end servers and supercomputers, there is a trend toward the use of methods of transmitting optical signals through circuit boards in place of methods of transmitting electric signals through circuit boards. An optical module converts an optical signal into an electric signal or converts an electric signal into an optical signal. For example, see Japanese Laid-open Patent Publication Nos. 2007-266130 and 2013-232637.

As illustrated in FIG. 11, an optical module 101 is mounted on a printed board 201 via land grid array (LGA) terminals 202 and is disposed on the periphery of a semiconductor chip 301. The optical module 101 is connected to an optical fiber 102. The semiconductor chip 301 is mounted on a package substrate 302. The package substrate 302 is mounted on the printed board 201 via BGA balls 203. A transmission path from the semiconductor chip 301 to the optical module 101 is established by the following components in the following order: the semiconductor chip 301, the package substrate 302, the BGA balls 203, the printed board 201, the LGA terminals 202, and the optical module 101.

The mounting position of the optical module 101 is preferably close to the semiconductor chip 301 so as to reduce the effect of transmission loss when a signal passes through the printed board 201. Therefore, as illustrated in FIG. 12, there is a case where the optical module 101 is mounted above the package substrate 302, as in, for example, a multi-chip module (MCM). A transmission path from the semiconductor chip 301 to the optical module 101 is established by the following components in the following order: the semiconductor chip 301, the package substrate 302, the LGA terminals 202, and the optical module 101.

From the standpoint of reliability, it is demanded that the optical module 101 be replaced when a failure occurs in the optical module 101. In order to facilitate the replacement process of the optical module 101, the optical module 101 and the package substrate 302 are connected to each other via an LGA socket or a connector to and from which the optical module 101 is attachable and detachable. When attaching or detaching the optical module 101, a force is applied to the BGA balls 203 that connect the printed board 201 and the package substrate 302 to each other, sometimes leading to detachment of the BGA balls 203.

The present application has been made in view of the problems mentioned above, and an object thereof is to provide a technology for suppressing detachment of solder that connects a printed board and a package substrate to each other.

### SUMMARY

According to an aspect of the invention, an optical module connector includes a connector configured to be coupled to a package substrate, which is coupled to first solder coupled to a printed board, and to second solder coupled to the printed board, the connector being coupled to the second solder; and an optical-module substrate configured to be detachably coupled to the connector, wherein the connector configured to include a first surface to which the optical-module substrate is coupled, a second surface coupled to the package substrate, and a third surface coupled to the second solder, and wherein the first surface to which the optical-module substrate is coupled includes a fourth surface opposite the second surface and a fifth surface opposite the third surface coupled to the second solder, and wherein a first height from the second surface to the first surface is less than a second height from the third surface to the first surface.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 schematically illustrates a printed board assembly according to a first embodiment;

FIG. 2 is a perspective view of an optical module connector;

FIG. 3 illustrates a connector;

FIG. 4 schematically illustrates the printed board assembly according to the first embodiment;

FIG. 5 schematically illustrates a printed board assembly according to a second embodiment;

FIG. 6 is a bottom view of a package substrate;

FIG. 7 is a bottom view of a connector;

FIG. 8 is a bottom view of a connector;

FIG. 9 schematically illustrates a printed board assembly according to a third embodiment;

FIG. 10 is an enlarged view of a connector;

FIG. 11 schematically illustrates a printed board;

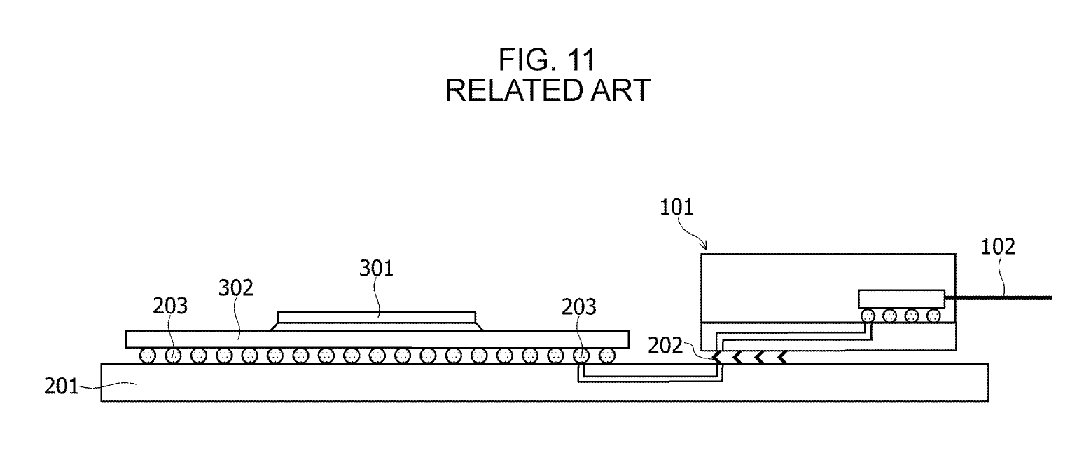

FIG. 12 schematically illustrates a printed board;

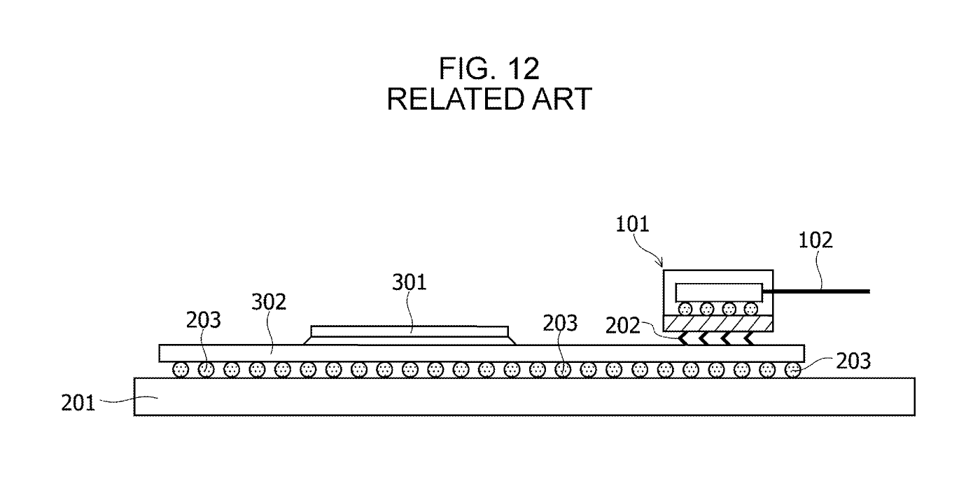

FIG. 13 schematically illustrates a printed board;

FIG. 14 schematically illustrates a printed board;

FIG. 15 schematically illustrates a printed board;

FIG. 16 schematically illustrates a printed board; and

FIG. 17 schematically illustrates a printed board.

### DESCRIPTION OF EMBODIMENTS

Hereinafter, embodiments will be described with reference to the drawings. The configurations of the embodiments are merely examples and are not limited thereto.

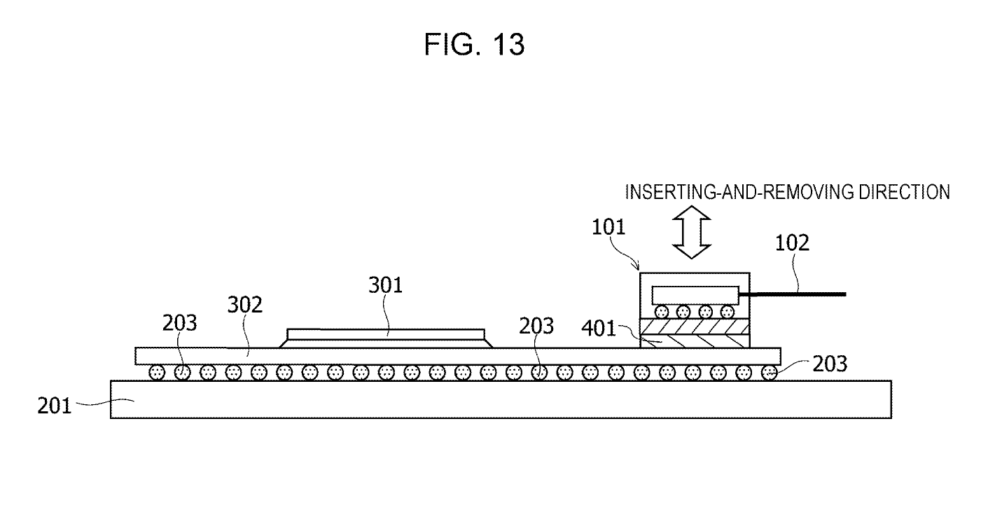

FIG. 13 through FIG. 17 schematically illustrate a printed board 201. As illustrated in FIG. 13, a connector 401 is coupled to a package substrate 302. By inserting or removing an optical module 101 into or from the connector 401, the optical module 101 is attached to or detached from the package substrate 302. In a case where the direction for inserting and removing the optical module 101 into and from the connector 401 is the vertical direction, as illustrated in FIG. 13, a vertical force is applied to ball-grid-array (BGA) balls 203, which connect the printed board 201 and the package substrate 302 to each other, when inserting or removing the optical module 101. An excessive force applied to the BGA balls 203 may sometimes lead to detachment of the BGA balls 203. For example, when inserting the optical module 101 into the connector 401, the package substrate 302 is pushed, causing the package substrate 302 to tilt. This may sometimes lead to detachment of the BGA balls 203. For example, when removing the optical module 101 from the connector 401, the package substrate 302 is lifted, sometimes leading to detachment of the BGA balls 203.

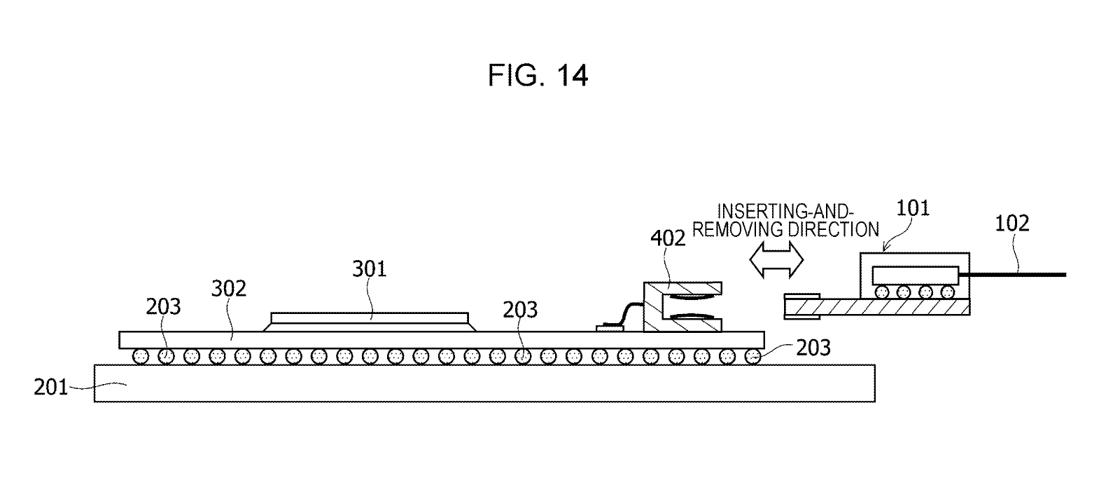

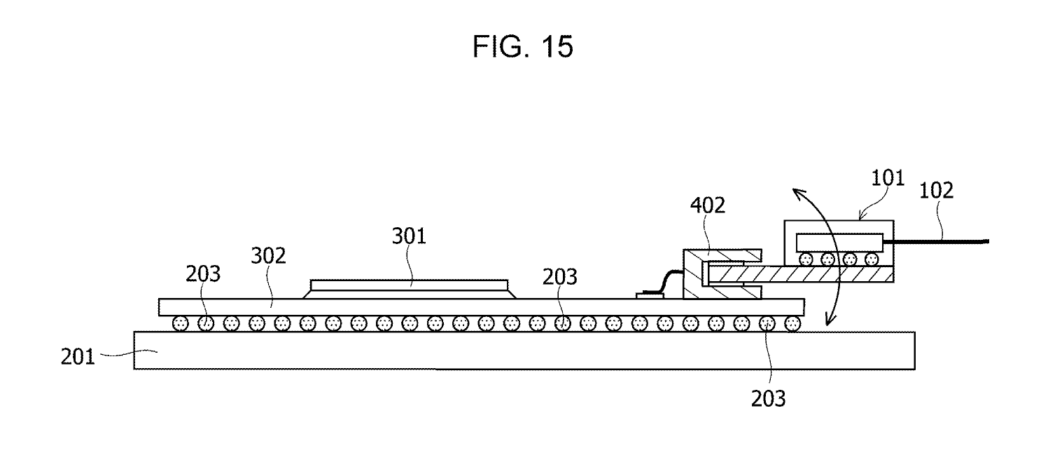

As illustrated in FIG. 14, a connector 402 is coupled to the package substrate 302. By inserting or removing the optical module 101 into or from the connector 402, the optical module 101 is attached to or detached from the package substrate 302. In a case where the direction for inserting and removing the optical module 101 into and from the connector 402 is the horizontal direction, as illustrated in FIG. 14, a vertical force applied to the BGA balls 203 when inserting or removing the optical module 101 decreases, as compared with the case where the inserting-and-removing direction of the optical module 101 is the vertical direction. However, as illustrated in FIG. 15, vibration or impact occurring when inserting or removing the optical module 101 may cause the optical module 101 to swivel in the vertical direction, sometimes causing an excessive force to be applied to the BGA balls 203.

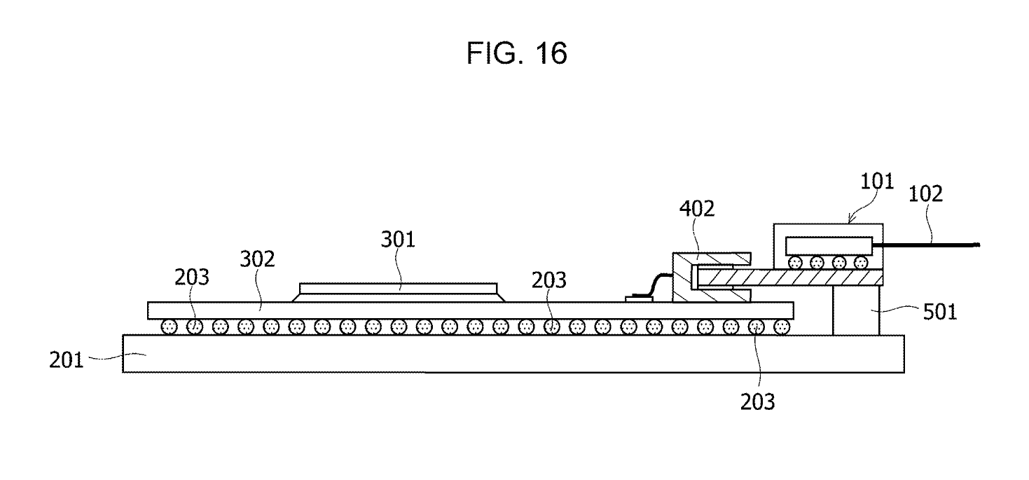

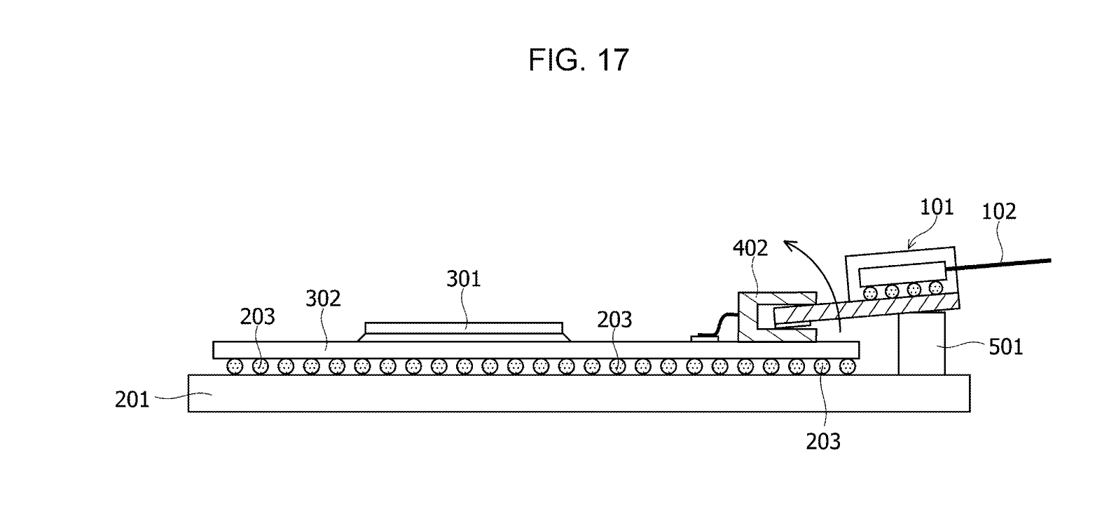

As illustrated in FIG. 16, in order to suppress vibration or impact occurring when inserting or removing the optical module 101, a stand-off 501 is sometimes provided on the printed board 201. The connector 402 is coupled to the package substrate 302, and the stand-off 501 is provided on the printed board 201. If the height of the connector 402 is different from the height of the stand-off 501, the optical module 101 may tilt when inserting the optical module 101 into the connector 402 or when mounting the optical module 101 on the stand-off 501, as illustrated in FIG. 17. If the optical module 101 is inserted or removed in the state where the optical module 101 is tilted, a vertical force may possibly be applied to the BGA balls 203. FIG. 17 illustrates a case where the height of the stand-off 501 is larger than the height of the connector 402. Therefore, it is preferable that the connector 402 and the stand-off 501 have an even height.

Making the height from the printed board 201 to the connector 402 equal to the height from the printed board 201 to the stand-off 501 may have an effect on the component tolerance of the connector 402, the component tolerance of the stand-off 501, and the component tolerance of the BGA balls 203. Because the connector 402 and the stand-off 501 are different components, it is difficult to make the height from the printed board 201 to the connector 402 equal to the height from the printed board 201 to the stand-off 501.

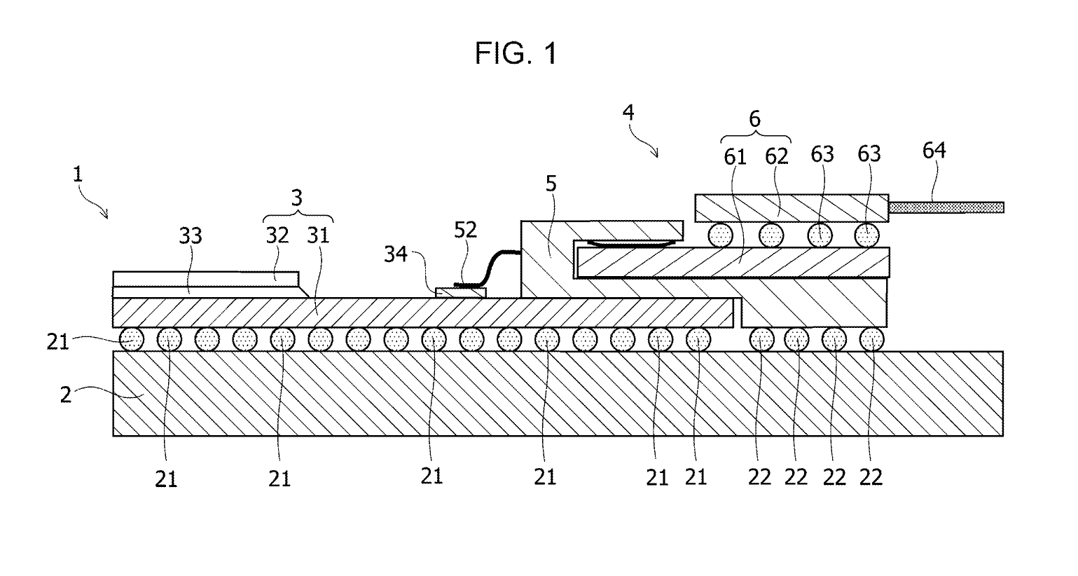

A first embodiment will now be described with reference to FIG. 1 through FIG. 4. FIG. 1 schematically illustrates a printed board assembly 1 according to the first embodiment. The printed board assembly 1 includes a printed board 2, a semiconductor package 3, and an optical module connector 4. The printed board assembly 1 is also called a printed board unit. The printed board 2 is also called a printed circuit board or a printed wiring board.

The semiconductor package 3 has a package (PKG) substrate 31 and a semiconductor chip 32 coupled to the package substrate 31. The package substrate 31 is composed of, for example, resin, such as epoxy resin, polyimide resin, or phenolic resin. The semiconductor chip 32 is, for example, large scale integration (LSI). In a state (face-down state) where the surface of the semiconductor chip 32 having a circuit thereon (referred to as “circuit surface” hereinafter) faces the package substrate 31, an electrode provided at the circuit surface of the semiconductor chip 32 and an electrode provided at the upper surface of the package substrate 31 are joined to each other via BGA balls. In FIG. 1, the electrode provided at the upper surface of the package substrate 31, the BGA balls, and the electrode of the semiconductor chip 32 are not illustrated.

The space between the package substrate 31 and the semiconductor chip 32 is filled with underfill resin 33. Pad electrodes 34 are provided on the package substrate 31. The pad electrodes 34 are electrically connected to the semiconductor chip 32 via wires provided within the package substrate 31. The package substrate 31 is coupled to a plurality of BGA balls 21 connected (arranged) to the printed board 2. Furthermore, the package substrate 31 is coupled to the plurality of BGA balls 21.

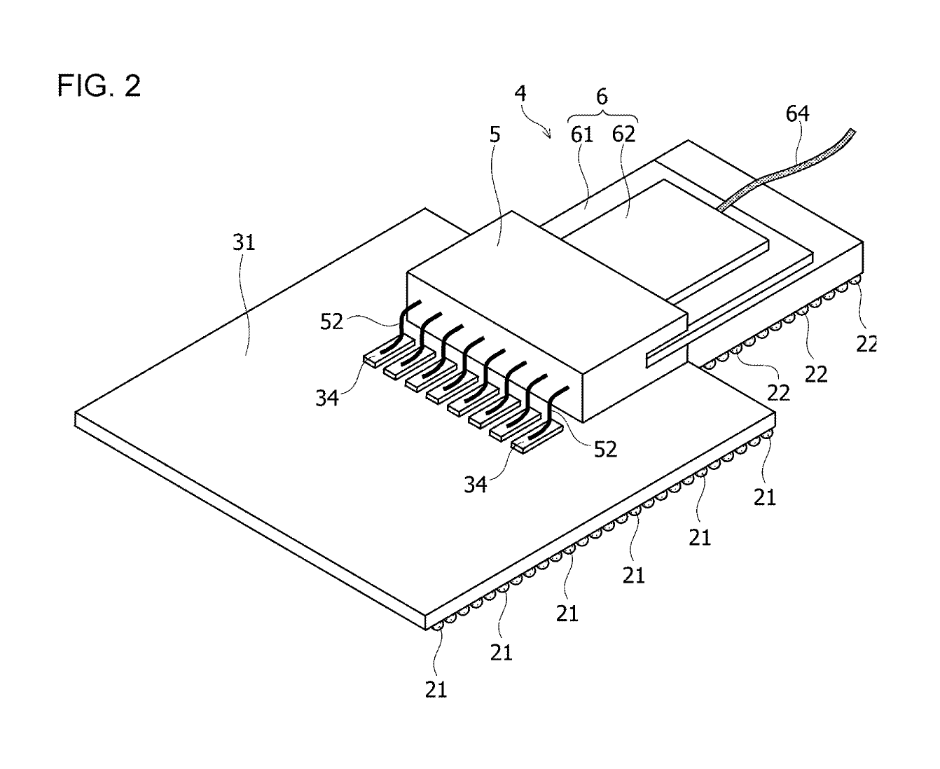

FIG. 2 is a perspective view of the optical module connector 4. The optical module connector 4 includes a connector 5 and an optical module 6 detachably coupled to the connector 5. The connector 5 is coupled to the package substrate 31 and is also coupled to a plurality of BGA balls 22 connected (arranged) to the printed board 2. Specifically, one part of the connector 5 is coupled to the package substrate 31, and the other part of the connector 5 is coupled to the plurality of BGA balls 22. Furthermore, the connector 5 is coupled to the plurality of BGA balls 22.

The BGA balls 21 and 22 are spherical balls (solder balls) composed of a solder material. The size and material of each BGA ball 21 are the same as the size and material of each BGA ball 22. The size of each BGA ball 21 includes the diameter and the volume of the BGA ball 21. The size of each BGA ball 22 includes the diameter and the volume of the BGA ball 22. The material of the BGA balls 21 and 22 is not particularly limited and may be, for example, an alloy, such as Sn—Ag, Sn—Cu, or Sn—Ag—Cu. The BGA balls 21 are an example of first solder. The BGA balls 22 are an example of second solder. As an alternative to the BGA balls 21 and 22, cylindrical or prismatic solder pellets may be used.

The connector 5 has the optical module 6 coupled therein. The optical module 6 has a substrate 61 and an optical transceiver 62. A plurality of BGA balls 63 are arranged between the substrate 61 and the optical transceiver 62. Electrodes provided at the upper surface of the substrate 61 and electrodes provided at the lower surface of the optical transceiver 62 are coupled to each other via the BGA balls 63. In FIG. 1 and FIG. 2, the electrodes provided at the upper surface of the substrate 61 and the electrodes provided at the lower surface of the optical transceiver 62 are not illustrated. The substrate 61 is composed of, for example, resin, such as epoxy resin, polyimide resin, or phenolic resin. The optical transceiver 62 is coupled to an optical fiber 64. The optical transceiver 62 has a light emitting element that converts an electric signal input via the connector 5 into light and a light receiving element that converts light input via the optical fiber 64 into an electric signal.

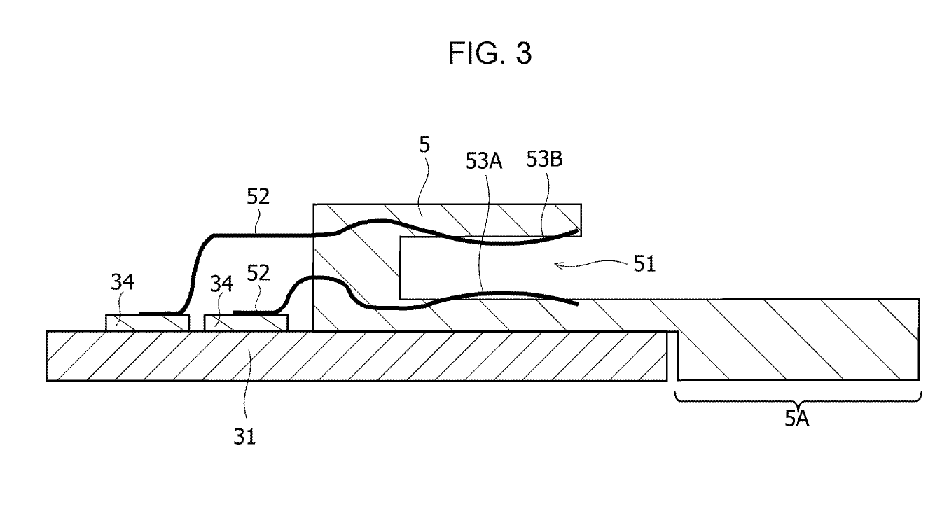

FIG. 3 illustrates the connector 5. The connector 5 has an insertion opening 51 into and from which the substrate 61 of the optical module 6 is insertable and removable, external lead wires 52 connected to the pad electrodes 34 on the package substrate 31, and internal lead wires 53A and 53B connected to the external lead wires 52. The connector 5 is composed of, for example, resin, such as epoxy resin, polyimide resin, or phenolic resin. The substrate 61 of the optical module 6 is inserted into the insertion opening 51 of the connector 5, so that the connector 5 and the optical module 6 become coupled to each other and the optical module 6 becomes accommodated within the connector 5. Accordingly, the connector 5 is of a type (right-angle type) in which the substrate 61 of the optical module 6 is horizontally inserted into the insertion opening 51 of the connector 5. The optical module 6 is of a type (card-edge type) in which the substrate 61 of the optical module 6 is inserted into the insertion opening 51 of the connector 5.

The internal lead wires 53A and 53B of the connector 5 and the electrodes provided at the substrate 61 of the optical module 6 are in contact with each other so that the connector 5 and the optical module 6 are electrically connected to each other. The connector 5 is electrically connected to the semiconductor chip 32. Therefore, the semiconductor chip 32 and the optical module 6 are electrically connected to each other via the connector 5. Exchanging of electric signals is performed between the semiconductor chip 32 and the optical module 6 via the external lead wires 52 and the internal lead wires 53A and 53B of the connector 5. Furthermore, electric power may be supplied from the semiconductor package 3 to the optical module 6 via the external lead wires 52 and the internal lead wires 53A and 53B of the connector 5.

When the optical module 6 is to be attached to the connector 5, the substrate 61 of the optical module 6 is inserted horizontally into the insertion opening 51 of the connector 5. When the optical module 6 is to be detached from the connector 5, the substrate 61 of the optical module 6 is removed horizontally from the insertion opening 51 of the connector 5. Therefore, the insertion and removal of the optical module 6 into and from the connector 5 is performed in the horizontal direction. By performing the insertion and removal of the optical module 6 into and from the connector 5 in the horizontal direction, a vertical force applied to the BGA balls 21 and 22 may be suppressed. Therefore, even when the optical module 6 is coupled to the connector 5 or the optical module 6 is disconnected from the connector 5, an excessive vertical force is not applied to the BGA balls 21 and 22. As a result, detachment of or damages to the BGA balls 21 and 22 may be suppressed.

The substrate 61 of the optical module 6 is inserted into the insertion opening 51 of the connector 5 in a state where the substrate 61 of the optical module 6 is in contact with the mounting surface of the connector 5. Furthermore, the substrate 61 of the optical module 6 is removed from the insertion opening 51 of the connector 5 in a state where the substrate 61 of the optical module 6 is in contact with the mounting surface of the connector 5. The mounting surface of the connector 5 is one of the surfaces of the connector 5 to which the optical module 6 is coupled. The connector 5 has a stand-off section (protrusion) 5A that protrudes outward relative to the contour of the package substrate 31 in plan view. The connector 5 and the stand-off section 5A are formed as a single unit. When inserting or removing the optical module 6 into or from the connector 5, the optical module 6 is in contact with the stand-off section 5A. Therefore, vibration or impact occurring when inserting or removing the optical module 6 into or from the connector 5 may be suppressed. Accordingly, a vertical force applied to the BGA balls 21 and 22 may be suppressed.

The internal lead wires 53A and 53B are bent, and the bent sections of the internal lead wires 53A and 53B protrude from the insertion opening 51 of the connector 5. When the substrate 61 of the optical module 6 is inserted into the insertion opening 51 of the connector 5, the internal lead wire 53A is set within the connector 5. For example, the mounting surface of the connector 5 may be provided with a recess. When the substrate 61 of the optical module 6 is inserted into the insertion opening 51 of the connector 5, the internal lead wire 53A becomes accommodated within the recess, and the internal lead wire 53A accommodated within the recess comes into contact with the electrode provided at the substrate 61.

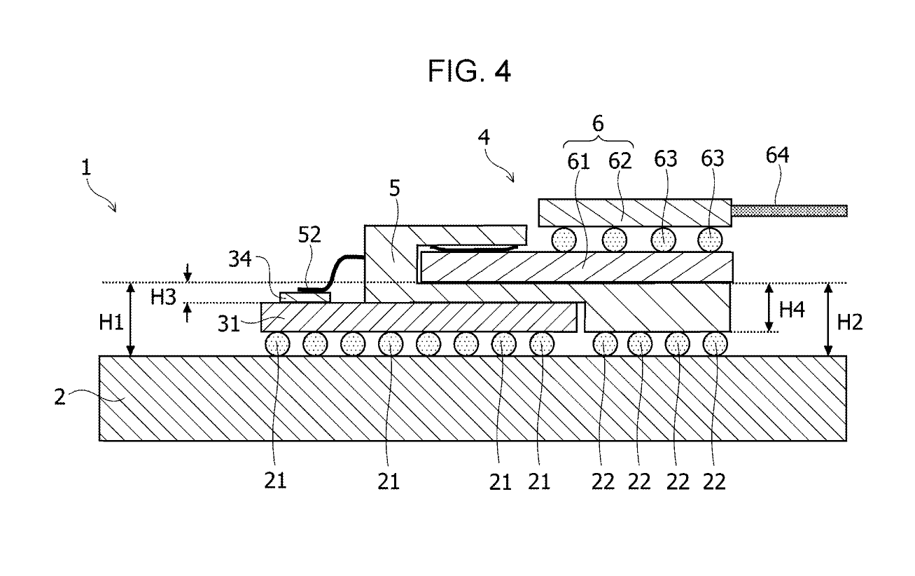

The mounting surface of the connector 5 is divided into a first surface and a second surface. The first surface is one of the surfaces of the connector 5 opposite the surface thereof in contact with the package substrate 31. The second surface is one of the surfaces of the connector 5 opposite the surface thereof coupled to the BGA balls 22. As illustrated in FIG. 4, the height (H1) from the printed board 2 to the mounting surface of the connector 5 is equal to the height (H2) from the printed board 2 to the mounting surface of the connector 5. Since the connector 5 and the stand-off section 5A are formed as a single unit, the component tolerance of the connector 5 and the component tolerance of the stand-off section 5A can be kept within the same component tolerance. Specifically, the connector 5 and the stand-off section 5A can be manufactured with the same tolerance. Furthermore, since the BGA balls 21 and the BGA balls 22 have identical sizes and are composed of identical materials, the height of the BGA balls 21 and the height of the BGA balls 22 are equal to each other.

Because the height (H1) from the printed board 2 to the mounting surface of the connector 5 is equal to the height (H2) from the printed board 2 to the mounting surface of the connector 5, the optical module 6 does not tilt when the optical module 6 is inserted into or removed from the connector 5. Since the optical module 6 can be inserted into or removed from the connector 5 without causing the optical module 6 to tilt, a vertical force applied to the BGA balls 21 and 22 may be suppressed. Therefore, even when the optical module 6 is coupled to the connector 5 or the optical module 6 is disconnected from the connector 5, an excessive vertical force is not applied to the BGA balls 21 and 22. As a result, detachment of or damages to the BGA balls 21 and 22 may be suppressed.

The height (H4) of the stand-off section 5A is larger than the height (H3) of the connector 5. The height (H3) of the connector 5 is the height measured from one of the surfaces of the connector 5 that is in contact with the package substrate 31 to the mounting surface of the connector 5. The height (H4) of the stand-off section 5A is the height measured from one of the surfaces of the connector 5 that is coupled to the BGA balls 22 to the mounting surface of the connector 5. The height (H3) of the connector 5 and the height (H4) of the stand-off section 5A are set in accordance with the thickness (height) of the package substrate 31. Specifically, a total value of the thickness of the package substrate 31 and the height (H3) of the connector 5 is equal to the height (H4) of the stand-off section 5A.

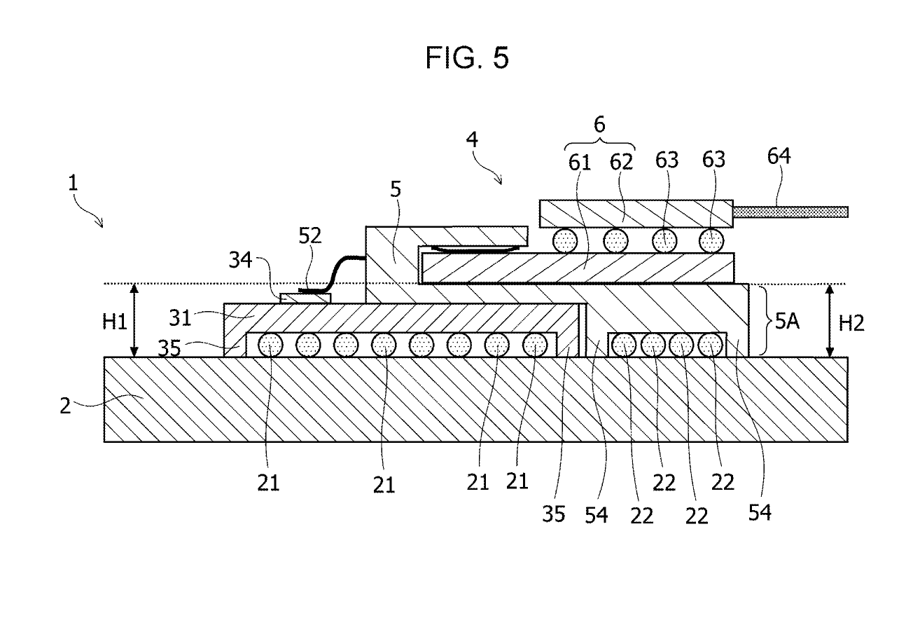

A second embodiment will now be described with reference to FIG. 5 through FIG. 8. In the second embodiment, components similar to those in the first embodiment are given the same reference signs as those in the first embodiment, and descriptions thereof will be omitted. FIG. 5 schematically illustrates the printed board assembly 1 according to the second embodiment. The package substrate 31 has a plurality of supports 35, and the connector 5 has a plurality of supports 54. The supports 35 are examples of first supports. The supports 54 are examples of second supports.

The supports 35 are located between the printed board 2 and the package substrate 31, and the supports 54 are located between the printed board 2 and the stand-off section 5A of the connector 5. The supports 35 and the supports 54 are in contact with the printed board 2. By disposing the supports 35 between the printed board 2 and the package substrate 31, the collapsing amount of the BGA balls 21 can be controlled. By disposing the supports 54 between the printed board 2 and the stand-off section 5A of the connector 5, the collapsing amount of the BGA balls 22 can be controlled. In FIG. 5, the semiconductor chip 32 and the underfill resin 33 are not illustrated.

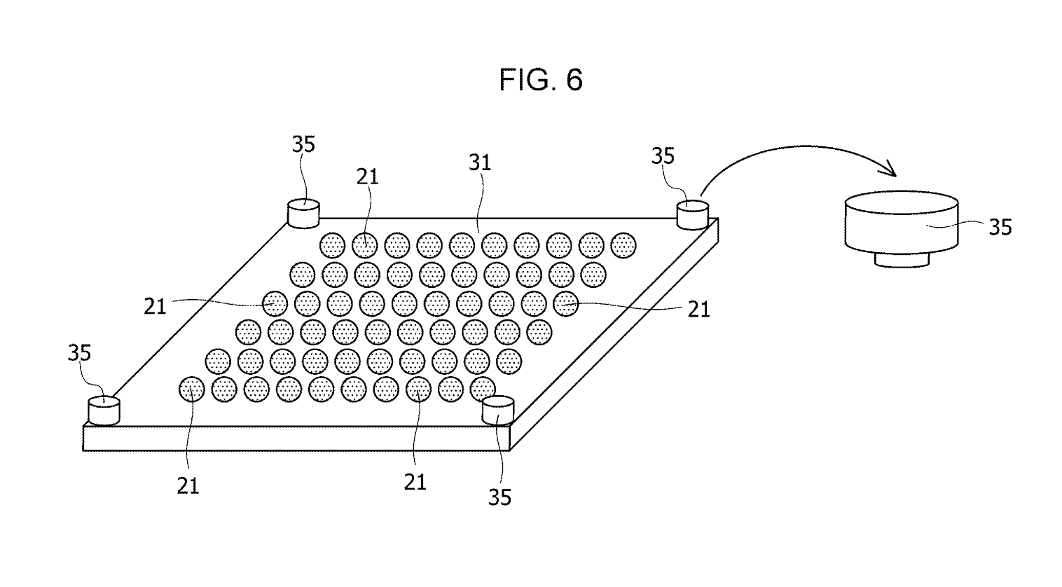

FIG. 6 is a bottom view (back view) of the package substrate 31. The lower surface of the package substrate 31 is provided with the supports 35 that suppress collapsing of the BGA balls 21. The supports 35 are composed of, for example, resin, such as epoxy resin, polyimide resin, or phenolic resin. The supports 35 may have a quadratic prism shape or a cylindrical shape.

In the example illustrated in FIG. 6, the supports 35 are provided at four corners of the lower surface of the package substrate 31. The second embodiment is not limited to the example illustrated in FIG. 6, and the supports 35 may be provided at freely-chosen locations of the lower surface of the package substrate 31. Furthermore, the number of supports 35 provided at the lower surface of the package substrate 31 may be one or more. The supports 35 may be fixed to the lower surface of the package substrate 31 by partially embedding the supports 35 in the package substrate 31. For example, as illustrated in FIG. 6, each support 35 may be provided with a protrusion, and the protrusion of the support 35 may be embedded in the package substrate 31. The collapsing amount of the BGA balls 21 is controlled by disposing the supports 35 between the printed board 2 and the package substrate 31, so that collapsing of the BGA balls 21 can be suppressed.

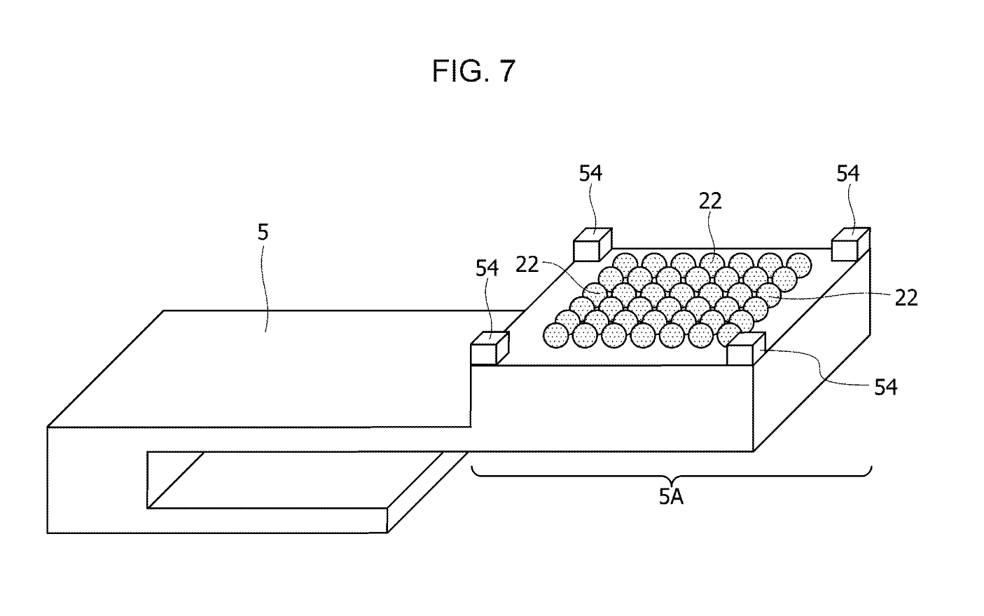

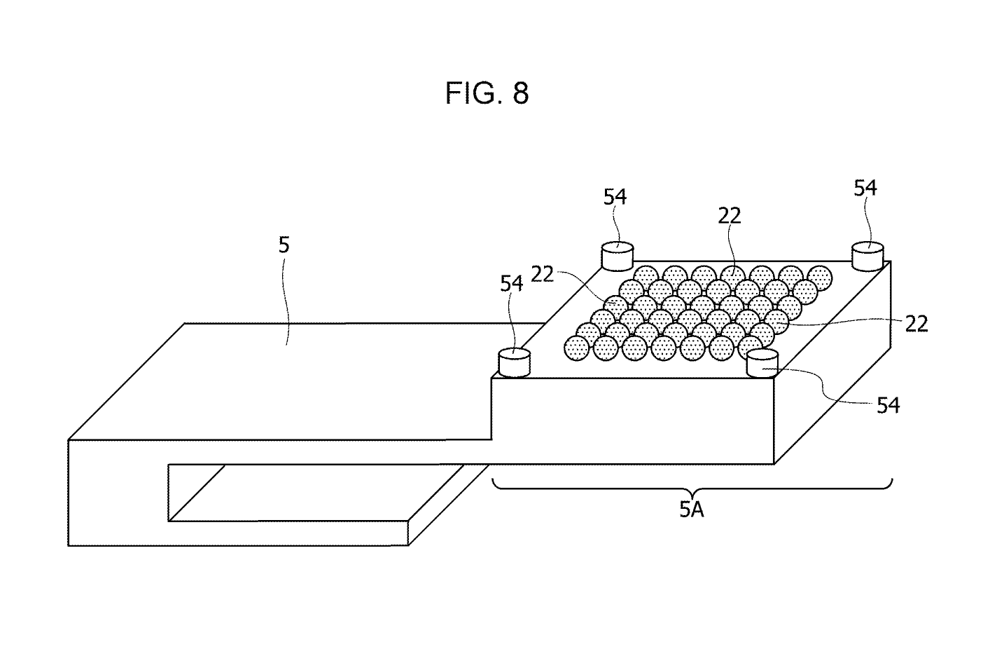

FIG. 7 and FIG. 8 are bottom views (back views) of the connector 5. The lower surface of the stand-off section 5A of the connector 5 is provided with the supports 54 that suppress collapsing of the BGA balls 22. The supports 54 are provided at four corners of the lower surface of the stand-off section 5A of the connector 5. The supports 54 are composed of, for example, resin, such as epoxy resin, polyimide resin, or phenolic resin. The connector 5, the stand-off section 5A, and the supports 54 are formed as a single unit. As illustrated in FIG. 7, the supports 54 may have a quadratic prism shape. As illustrated in FIG. 8, the supports 54 may have a cylindrical shape.

In the examples illustrated in FIG. 7 and FIG. 8, the supports 54 are provided at the four corners of the lower surface of the stand-off section 5A of the connector 5. The second embodiment is not limited to the examples illustrated in FIG. 7 and FIG. 8. The supports 54 may be provided at freely-chosen locations of the lower surface of the stand-off section 5A of the connector 5. Furthermore, the number of supports 54 provided at the lower surface of the stand-off section 5A of the connector 5 may be one or more. The collapsing amount of the BGA balls 22 is controlled by disposing the supports 54 between the printed board 2 and the stand-off section 5A of the connector 5, so that collapsing of the BGA balls 22 can be suppressed.

As illustrated in FIG. 5, the height (H1) from the printed board 2 to the mounting surface of the connector 5 is equal to the height (H2) from the printed board 2 to the mounting surface of the connector 5. Since the connector 5, the stand-off section 5A, and the supports 54 are formed as a single unit, the component tolerance of the connector 5, the component tolerance of the stand-off section 5A, and the component tolerance of the supports 54 can be kept within the same component tolerance. Specifically, the connector 5, the stand-off section 5A, and the supports 54 can be manufactured with the same tolerance.

Because the height (H1) from the printed board 2 to the mounting surface of the connector 5 is equal to the height (H2) from the printed board 2 to the mounting surface of the connector 5, the optical module 6 does not tilt when the optical module 6 is inserted into or removed from the connector 5. Since the optical module 6 can be inserted into or removed from the connector 5 without causing the optical module 6 to tilt, a vertical force applied to the BGA balls 21 and 22 may be suppressed. Therefore, even when the optical module 6 is coupled to the connector 5 or the optical module 6 is disconnected from the connector 5, an excessive vertical force is not applied to the BGA balls 21 and 22. As a result, detachment of or damages to the BGA balls 21 and 22 may be suppressed.

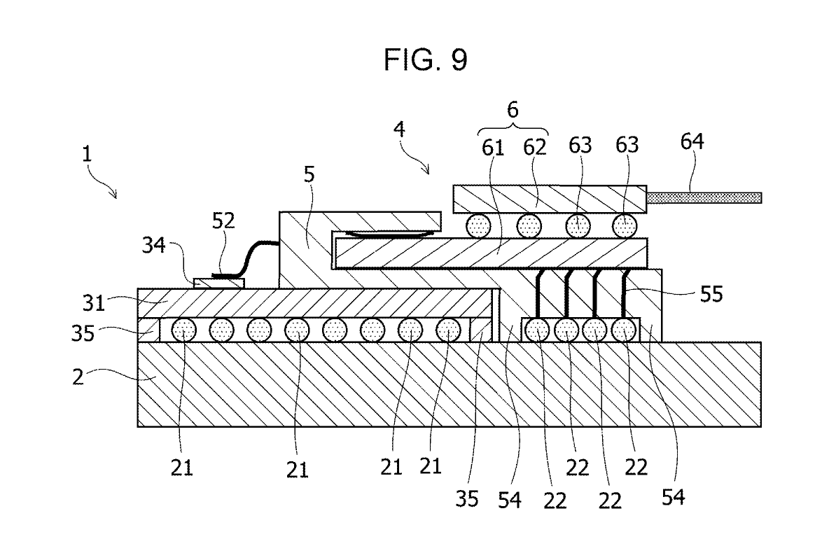

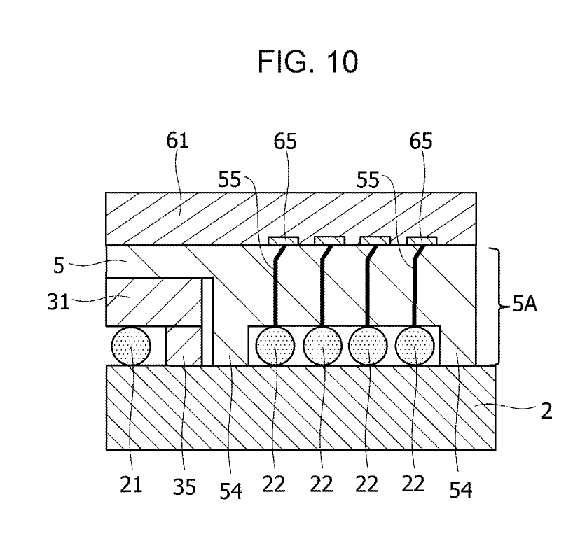

A third embodiment will now be described with reference to FIG. 9 and FIG. 10. In the third embodiment, components similar to those in the first and second embodiments are given the same reference signs as those in the first and second embodiments, and descriptions thereof will be omitted. FIG. 9 schematically illustrates the printed board assembly 1 according to the third embodiment. FIG. 10 is an enlarged view of the connector 5. The connector 5 has a plurality of connection terminals 55 coupled to the plurality of BGA balls 22. The plurality of connection terminals 55 are contained inside the stand-off section 5A of the connector 5. The connection terminals 55 may be, for example, land grid array terminals arranged in a grid pattern.

Pad electrodes 65 provided at the lower surface of the substrate 61 of the optical module 6 are coupled to the BGA balls 63 of the optical module 6 via wires provided within the substrate 61 of the optical module 6. As illustrated in FIG. 9 and FIG. 10, when the optical module 6 is accommodated in the connector 5, the plurality of pad electrodes 65 provided at the lower surface of the substrate 61 of the optical module 6 are in contact with the plurality of connection terminals 55. Accordingly, the optical module 6 and the connection terminals 55 are electrically coupled to each other.

According to the third embodiment, electric power can be supplied directly from the printed board 2 to the optical module 6 via the BGA balls 22 and the connection terminals 55. Therefore, in the third embodiment, exchanging of high-speed signals is performed via the external lead wires 52 and the internal lead wires 53A and 53B of the connector 5, and power supply is performed via the connection terminals 55 of the connector 5 and the BGA balls 22.

In the example illustrated in FIG. 9 and FIG. 10, the package substrate 31 has the supports 35, and the connector 5 has the supports 54. The third embodiment is not limited to the example illustrated in FIG. 9 and FIG. 10. The supports 35 for the package substrate 31 may be omitted, or the supports 54 for the connector 5 may be omitted.

The following are subjoinders related to the above embodiments

Note 1. An optical module connector includes: a connector configured to be mounted on a package substrate, which is mounted on first solder connected on a printed board, and on second solder connected on the printed board, the connector being connected to the second solder; and an optical-module substrate configured to be detachably mounted in the connector, wherein the connector configured to include a first surface on which the optical-module substrate is mounted, a second surface in contact with the package substrate, and a third surface connected to the second solder, and wherein the first surface on which the optical-module substrate is mounted includes a fourth surface opposite the second surface and a fifth surface opposite the third surface connected to the second solder, and wherein a first height from the second surface to the first surface is less than a second height from the third surface to the first surface.

Note 2. The optical module connector according to note 1, wherein the connector includes an area where a height from the printed board to the fourth surface and a height from the printed board to the fifth surface are equal to each other.

Note 3. The optical module connector according to note 1, wherein the package substrate has a first support located between the printed board and the package substrate, and wherein the connector has a second support located between the printed board and the connector.

Note 4. The optical module connector according to note 1, wherein the connector has a connection terminal connected to the second solder, and wherein when the optical-module substrate is mounted in the connector, the optical-module substrate and the connection terminal are connected to each other.

Note 5. The optical module connector according to note 1, wherein the first solder and the second solder are composed of identical materials and have identical sizes.

Note 6. A printed board assembly includes: a printed board; a package substrate configured to be mounted on first solder, which is connected on the printed board, and connected to the first solder; a connector configured to be mounted on the package substrate and on second solder connected on the printed board, the connector being connected to the second solder; and an optical-module substrate configured to be detachably mounted in the connector, wherein the connector is configured to include a first surface on which the optical-module substrate is mounted, a second surface in contact with the package substrate, and a third surface connected to the second solder, and wherein the first surface on which the optical module is mounted is divided into a fourth surface opposite the second surface and a fifth surface opposite the third surface connected to the second solder, and wherein a first height from the second surface to the first surface is less than a second height from the third surface to the first surface.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An optical module connector, comprising:
a connector configured to be coupled to a package substrate, which is coupled to first solder coupled to a printed board, and to second solder coupled to the printed board, the connector being coupled to the second solder; and
an optical-module substrate configured to be detachably coupled to the connector,
wherein the connector configured to include a first surface to which the optical-module substrate is coupled, a second surface coupled to the package substrate, and a third surface coupled to the second solder, and wherein the first surface to which the optical-module substrate is coupled includes a fourth surface opposite the second surface and a fifth surface opposite the third surface coupled to the second solder, and
wherein a first height from the second surface to the first surface is less than a second height from the third surface to the first surface.

2. The optical module connector according to claim 1,
wherein the connector includes an area where a height from the printed board to the fourth surface and a height from the printed board to the fifth surface are equal to each other.

3. The optical module connector according to claim 1,
wherein the package substrate has a first support located between the printed board and the package substrate, and
wherein the connector has a second support located between the printed board and the connector.

4. The optical module connector according to claim 1,
wherein the connector has a connection terminal coupled to the second solder, and
wherein when the optical-module substrate is coupled to the connector, the optical-module substrate and the connection terminal are coupled to each other.

5. The optical module connector according to claim 1,
wherein the first solder and the second solder are composed of identical materials and have identical sizes.

6. A printed board assembly, comprising:
a printed board;
a package substrate configured to be coupled to first solder, which is coupled to the printed board;
a connector configured to be coupled to the package substrate and to second solder coupled to the printed board, the connector being coupled to the second solder; and
an optical-module substrate configured to be detachably coupled to the connector,
wherein the connector is configured to include a first surface to which the optical-module substrate is coupled, a second surface coupled to the package substrate, and a third surface coupled to the second solder, and wherein the first surface to which the optical module is coupled is divided into a fourth surface opposite the second surface and a fifth surface opposite the third surface coupled to the second solder, and
wherein a first height from the second surface to the first surface is less than a second height from the third surface to the first surface.
